(19) United States
(12) Patent Application Publication
(10) Pub. No.: US 2023/0223240 A1
(43) Pub. Date: Jul. 13, 2023

(54) MATCHED CHEMISTRY COMPONENT BODY AND COATING FOR SEMICONDUCTOR PROCESSING CHAMBER

(71) Applicant: Lam Research Corporation, Fremont, CA (US)

(72) Inventors: Eric A. PAPE, Santa Cruz, CA (US); Douglas DETERT, Berkeley, CA (US)

(21) Appl. No.: 18/009,903

(22) PCT Filed: Jun. 16, 2021
(86) PCT No.: PCT/US2021/037697

§ 371 Date: Dec. 12, 2022

Related U.S. Application Data
(60) Provisional application No. 63/044,007, filed on Jun. 25, 2020.

(51) Int. Cl. H01J 37/32

(52) U.S. Cl. CPC H01J 37/32495; H01J 37/32807; H01J 37/32642; H01J 37/32119

(57) ABSTRACT

A component for use in a semiconductor processing chamber is provided. A component body of a dielectric material has a semiconductor processing facing surface. A coating of a dielectric material is on at least the semiconductor processing facing surface, wherein the dielectric material of the component body has a same stoichiometry as the dielectric material of the coating.

### CROSS REFERENCE TO RELATED APPLICATION

This application claims the benefit of priority of U.S. Application No. 63/044,007, filed Jun. 25, 2020, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In forming semiconductor devices plasma processing chambers are used to process the substrates. Some plasma processing chambers have component parts that are eroded during plasma processing. Coatings may be used to protect the component parts. However, temperature differentials and other factors may cause the coatings to delaminate from the component part.

Some plasma processing chambers have dielectric components with plasma facing surfaces. The dielectric parts may be formed from ceramic alumina. The machining of the alumina part may cause damage and defects. Such defects may cause problems, primarily with particle generation from such components.

### SUMMARY

To achieve the foregoing and in accordance with the purpose of the present disclosure, a method for making a component for use in a semiconductor processing chamber is provided. A component body is formed from a dielectric material, wherein the component body has a semiconductor processing facing surface. A coating of the dielectric material is deposited over at least the semiconductor processing facing surface of the component body.

In another manifestation, a component for use in a semiconductor processing chamber is provided. A component body of a dielectric material has a semiconductor processing facing surface. A coating of a dielectric material is on at least the semiconductor processing facing surface, wherein the dielectric material of the component body has a same stoichiometry as the dielectric material of the coating.

In another manifestation, a method of reconditioning a component body of a dielectric material for use in a semiconductor processing chamber is provided. At least part of a process facing surface of the component is stripped. A coating of the dielectric material is deposited on the component body.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2A-C is a schematic cross-sectional view of part of an embodiment

FIG. 3 is a schematic view of a semiconductor processing chamber that may be used in an embodiment.

FIG. 4 is a schematic cross-sectional view of part of another embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Coatings such as alumina, yttria, and yttrium aluminum oxide are used as coatings in some plasma processing chamber. Alumina is used over aluminum liners, yttria is used over alumina or aluminum pinnacles and windows. However, there remain problems, primarily with particle generation from such coatings and with coating adhesion. Such components are subject to machining damage. Such damage is subject to chemical attack, thermal expansion and contraction, and stresses from the deposition of material, resulting in the creation of particle contaminants. In addition, alumina may create aluminum fluoride particle contaminants.

In providing a power window and gas injector for an inductively coupled plasma processing chamber, it has been found that alumina is a good material for forming the body of such components due to the lower cost, machinability, and/or material properties (such as loss tangent) of alumina. However, a sintered bulk alumina body often has chemical impurities and can be polished only to a certain extent for roughness, and will have sub-surface damage from machining or polishing. In addition, a bulk alumina body may have a specific crystal structure, such as corundum and grain boundaries that are characteristic of the size scale. Grain orientations, crystal structure, and grain size or boundaries may all be non-ideal for bulk materials. If one can retain the key bulk properties (mechanical strength and stability, dielectric constant, loss tangent) and add in a surface coating that has optimal properties, overall performance of the component may be improved. It has been found that an atomic layer deposition coating (ALD) can fill in holes or pores, eliminate direct contact of a component body with plasma, and can provide a controlled crystal phase. Such a coating can change the plasma wetted surface to tailor the response of the coating to both chemical and ion attack. If an yttria coating is deposited on alumina, the yttria strongly fluorinates. Then, either directly or subsequently through redeposition, the fluorinated yttria creates particles that can fall on a wafer. Additionally, the yttria morphology and density are more difficult to control than the alumina morphology and density for a variety of deposition techniques. These ‘poor’ material properties of yttria result in increased plasma damage and particle generation. Therefore, in this embodiment, an alumina coating would be formed by an ALD process over an alumina sintered body.

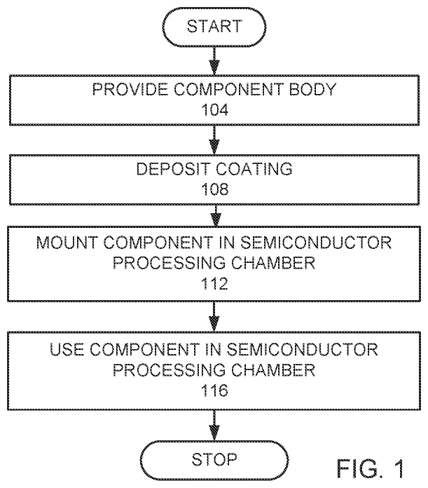

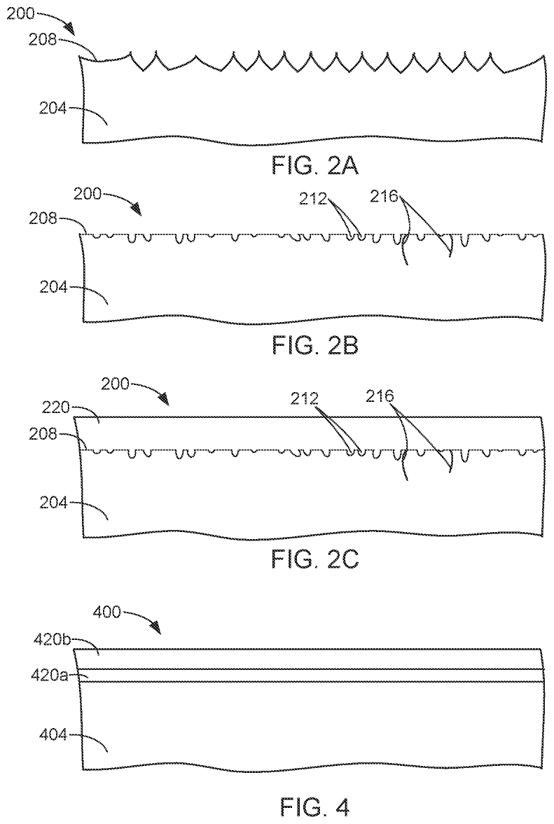

To facilitate understanding, FIG. 1 is a high level flow chart of a process used in an embodiment. A component body is provided (step 104). The component body may be formed by sintering a conductive ceramic powder. FIG. 2A is a schematic cross-sectional view of part of a component body 204. In this example, the component body 204 forms a power window. In this embodiment, the component body 204 is formed from a dielectric ceramic metal oxide. In this embodiment, the component body 204 is formed from sintered alumina. The component body 204 has a plasma facing surface 208. The plasma facing surface 208 is schematically illustrated as being rough with peaks and valleys. More generally, the plasma facing surface 208 is a semiconductor processing facing surface, where the semiconductor processing may be a plasma process or a plasmaless process.

In this embodiment, sintering is used to form a ceramic alumina component body 204 from an alumina ceramic powder. The sintered alumina body may be created by using various sintering processes, such as cold pressed, hot pressed, warm pressed, hot isostatic press, green sheet, and spark plasma sintering. In some embodiments, the component body 204 may be heated to at least 400° C. for at least 2 hours. In some embodiments, the component is heated for at least 1 day.

In this embodiment, the component body 204 is machined and polished. The machining and polishing are used to shape the component body and to change the morphology of the plasma facing surface 208. FIG. 2B is a schematic cross-sectional view of part of the component body 204 after the component body 204 has been machined and polished. The rough plasma facing surface 208 has been made smoother. The plasma facing surface 208 of the sintered component body 204 has pores 212. The pores 212 may be the result of the porous structure of the component body 204. In addition, in this embodiment, the plasma facing surface 208 has damage 216 caused by the machining of the component body 204. In other embodiments, the component body 204 is not machined or polished or both. For example, the component body 204 may be formed close enough to the final shape so that machining in not needed. In this embodiment, the entire component body 204 of the power window is made of a single dielectric material. The single single dielectric material may be a single dielectric metal containing material, such as alumina.

After the component body 204 is machined and polished, a coating is deposited on the plasma facing surface 208 of the component body (step 108). In this embodiment, an alumina coating is deposited on the alumina component body 204 using atomic layer deposition. In this embodiment, the ALD process comprises a plurality of cycles. In each cycle in this embodiment, first, a precursor is deposited. In this example, the precursor is trimethylaluminum. Next, a first purge is provided. In this example, a purge gas of N₂ is flowed to purge undeposited precursor. Then, a reactant is applied. In this example, the reactant is water. The reactant oxidizes the aluminum to form a monolayer of alumina. Next, a second purge is provided. In this example, a purge gas of N₂ is flowed to purge the reactant that remains as a vapor. This cycle is repeated for a plurality of cycles, forming the ALD alumina coating. In this example, the ALD process is plasmaless. In some emobodiments, the coating may be applied to other surfaces of the component body 204 in addition to the plasma facing surface 208.

FIG. 2C is a schematic cross-sectional view of part of the component body 204 after a coating 220 has been deposited (step 108). In this embodiment, the coating 220 fills in the pores 212 and covers the damage 216 providing a smooth nonporous surface. In other embodiments, the coating 220 may be more conformal or a deposition process may be chosen and tuned to provide a desired surface morphology.

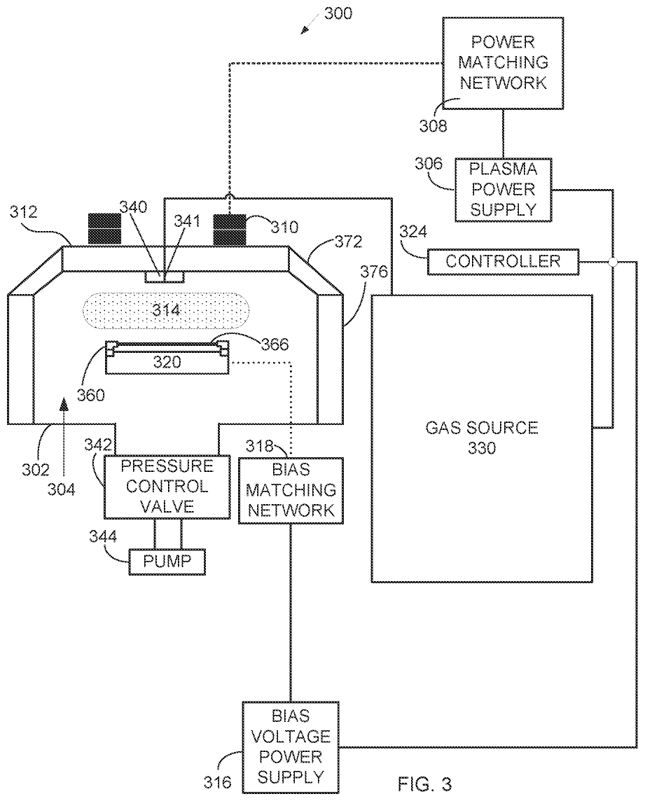

The component body 204 is mounted in a semiconductor processing chamber (step 112). In this embodiment, the component body 204 may be used as a power window or a gas injector in a semiconductor processing chamber. To facilitate understanding, FIG. 3 schematically illustrates an example of a semiconductor processing chamber system 300 that may be used in an embodiment. The semiconductor processing chamber system 300 includes a plasma reactor 302 having a semiconductor processing chamber 304 therein. A plasma power supply 306, tuned by a power matching network 308, supplies power to a transformer coupled plasma (TCP) coil 310 located near a dielectric inductive power window 312 to create a plasma 314 in the semiconductor processing chamber 304 by providing an inductively coupled power. A pinnacle 372 extends from a chamber wall 376 of the semiconductor processing chamber 304 to the dielectric inductive power window 312 forming a pinnacle ring. The pinnacle 372 is angled with respect to the chamber wall 376 and the dielectric inductive power window 312. For example, the interior angle between the pinnacle 372 and the chamber wall 376 and the interior angle between the pinnacle 372 and the dielectric inductive power window 312 may each be greater than 90° and less than 180°. The pinnacle 372 provides an angled ring near the top of the semiconductor processing chamber 304, as shown. The TCP coil (upper power source) 310 may be configured to produce a uniform diffusion profile within the semiconductor processing chamber 304. For example, the TCP coil 310 may be configured to generate a toroidal power distribution in the plasma 314. The dielectric inductive power window 312 is provided to separate the TCP coil 310 from the semiconductor processing chamber 304 while allowing energy to pass from the TCP coil 310 to the semiconductor processing chamber 304. A wafer bias voltage power supply 316 tuned by a bias matching network 318 provides power to an electrode 320 to set the bias voltage when a stack is placed on the electrode 320. A process wafer 366 is placed over the electrode 320. A controller 324 controls the plasma power supply 306 and the wafer bias voltage power supply 316.

The plasma power supply 306 and the wafer bias voltage power supply 316 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve desired process performance For example, in one embodiment, the plasma power supply 306 may supply the power in a range of 50 to 5000 Watts, and the wafer bias voltage power supply 316 may supply a bias voltage of in a range of 20 to 2000 volts (V). In addition, the TCP coil 310 and/or the electrode 320 may be comprised of two or more sub-coils or sub-electrodes. The sub-coils or sub-electrodes may be powered by a single power supply or powered by multiple power supplies.

As shown in FIG. 3, the semiconductor processing chamber system 300 further includes a gas source/gas supply mechanism 330. The gas source 330 is in fluid connection with semiconductor processing chamber 304 through a gas inlet, such as a gas injector 340. The gas injector 340 has at least one borehole 341 to allow gas to pass through the gas injector 340 into the semiconductor processing chamber 304. The gas injector 340 may be located in any advantageous location in the semiconductor processing chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process chamber 304. More preferably, the gas injector is mounted to the dielectric inductive power window 312. The gas injector may be mounted on, mounted in, or form part of the power window. The process gases and by-products are removed from the plasma process chamber 304 via a pressure control valve 342 and a pump 344. The pressure control valve 342 and pump 344 also serve to maintain a particular pressure within the semiconductor processing chamber 304. The pressure control valve 342 can maintain a pressure of less than 1 torr during processing. An edge ring 360 is placed around a top part of the electrode 320. The gas source/gas supply mechanism 330 is controlled by the controller 324. A Kiyo by Lam Research Corp. of Fremont, Calif., may be used to practice an embodiment.

In this embodiment, since both the component body 204 and the coating 220 are made of alumina, the component body 204 and coating 220 have almost the same coefficient of thermal expansion (CTE). The component body 204 is sintered, and the coating 220 is non-sintered. Therefore, when the component 200 is exposed to a wide range of temperatures, delamination between the component body 204 and coating 220 is reduced. In this embodiment, the coating 220 deposited by an ALD process has a higher purity of alumina than that component body 204, reducing contaminants caused by the impurities. The coating 220 provides a plasma facing surface with less machine damage and fewer pores further reducing contaminants. The surface morphology of the coating 220 may be tuned for different qualities. For example, the roughness and shape of the surface may be tuned to increase adherence of deposition during the plasma processing. The increased adherence reduces contaminants. In other embodiments, the coating 220 may have a lower purity than the component body 204.

Ex-situ fluorination data on various materials indicates that surface morphology (roughness), exposed plasma material phase structure (type of alumina crystal, as well as size, grain boundaries, interstitial materials, spectral frequency) have a significant effect on the ultimate performance of a plasma exposed material for particle generation. As a result, in some embodiments, the component body 204 and the coating 220 have different crystal structures. Providing a coating of the same material on a component body can be used to control surface properties while matching CTE and other properties of the component body 204, allowing for better thermal and mechanical stability and retention of other desired bulk properties. Various embodiments are able to simultaneously provide a desired surface morphology while healing defects from machining If the coating 220 was of a different material than the material of the component body 204, the defects may not be healed as completely. The coating 220 can change the plasma facing surface to tailor a response in regards to both chemical an ion attack.

Various semiconductor processing chamber systems 300 may use other components with a component body 204 of a dielectric material and a coating 220 of the same dielectric material so that the component body 204 and the coating 220 are of the same chemical compound having the same stoichiometry. Such components include ceramic plates for an ESC, dielectric inductive power windows, gas injectors, edge rings, chamber liners, such as a chamber pinnacle, chamber walls, showerheads, or ceramic transfer arms. Chamber walls, such as dome shaped chamber walls may have a complex geometry that may require machining to provide the complex geometry. The deposited coating provides a more resistant surface over the machined surface. For ceramic transfer arms, the coating would mitigate surface particulates. The ceramic transfer arms are not exposed to plasma. Therefore, in various embodiments the coating is also formed on surfaces of a component that are not a plasma facing surface of the component of a semiconductor processing chamber system 300. The component 200 may be used as a consumable semiconductor processing chamber component. The component 200 may be used in other types of semiconductor processing chambers for etching, deposition, or other plasma processes. Examples of other types of semiconductor processing chamber in which the component 200 may be used are capacitively coupled semiconductor processing chambers and bevel semiconductor processing chambers.

In other embodiments, the component body 204 and the coating 220 may be made of other dielectric materials. Such dielectric materials may be dielectric metal containing materials, such as one or more of metal oxides, metal oxyfluorides, and metal fluorides. Such metal oxides may be alumina, yttria (Y₂O₃), ternary yttria-alumina oxides such as yttrium aluminum garnet (Y₃Al₅O₁₂ (YAG)), yttrium aluminum monoclinic (Y₄Al₂O₉ (YAM)), or yttrium aluminum perovskite (YAlO₃ (YAP)), or YSZ (yttrium stabilized zirconia). Other metal oxides that may be used are rare earth metal oxides. An example of a metal oxyfluoride is yttrium oxyfluoride (YOF). An example of a metal fluoride is yttrium(III) fluoride (YF₃). In other embodiments, other composite ceramics that contain alumina, yttria, magnesium aluminum oxide, or magnesium oxide (MgO) phases may be used.

In various embodiments, the component body 204 may be a sintered component body or maybe a single crystal, or polycrystalline. In various embodiments, the entire component and component body is made of sintered dielectric ceramic of a dielectric material, instead of only a sleeve or coating on a component body being made of a sintered ceramic with the remaining part of the component being aluminum or an aluminum alloy. In various embodiments, different processes may be used for depositing the coating 220. For example, in some embodiments, physical vapor deposition (PVD), chemical vapor deposition (CVD), atomic layer deposition (ALD), aerosol deposition (AD), or various forms of thermal spray coating, such as atmospheric plasma spraying (APS) or suspension plasma spraying (SPS) may be used.

In an embodiment, a dielectric inductive power window 312 is provided. An alumina coating is deposited on an alumina component body using either an atmospheric plasma spray (APS) or a suspension plasma spray (SPS).

Atmospheric plasma spraying (APS) is a type of thermal spraying in which a torch is formed by applying an electrical potential between two electrodes, leading to ionization of an accelerated gas (a plasma). Torches of this type can readily reach temperatures of thousands of degrees Celsius, liquefying high melting point materials such as ceramics. Particles of the desired materials, in this embodiment alumina, are injected into the jet, melted, and then accelerated towards the substrate so that the molten or plasticized material coats the surface of the component and cool, forming a solid, conformal coating. These processes are distinct from vapor deposition processes that use vaporized material instead of molten material.

Suspension plasma spraying is a type of thermal spraying in which a torch is formed by applying an electrical potential between two electrodes, leading to ionization of an accelerated gas (a plasma). Torches of this type can readily reach temperatures of thousands of degrees Celsius, liquifying high melting point materials such as ceramics. A liquid suspension of solid particles to be deposited in a liquid medium is fed to the torch. The torch melts the solid particles of the desired material. A carrier gas is pushed through an arc cavity and out through a nozzle. In the cavity, a cathode and anode comprise parts of the arc cavity and are maintained at a large direct current (DC) bias voltage, until the carrier gas begins to ionize, forming the plasma. The hot, ionized gas is in then pushed out through the nozzle, forming the torch. Fluidized ceramic particles, less than 10 microns in size, are injected into the chamber near the nozzle. These particles are heated by the hot, ionized gas in the plasma torch such that they exceed the melting temperature of the ceramic. The jet of plasma and melted ceramic are then aimed at the component body. The particles impact the component body and are flattened and cooled to form a coating.

In this embodiment, the coating has a thickness in the range of 50 microns to 200 microns. In addition, in this embodiment, the coating has a surface roughness RA in the range of 100 microinches to 250 microinches (2.54 microns to 6.35 microns). In other embodiments, the coating may have a thickness between 30 nanometers (nm) and 150 microns.

In another embodiment, a dielectric inductive power window 312 is provided by first providing a YAG component body. Aerosol deposition (AD) is used to deposit a YAG coating on the component body. Aerosol deposition is achieved by passing a carrier gas through a fluidized bed of solid powder mixture. Driven by a pressure difference, the powder particles are accelerated through a nozzle, forming an aerosol jet at its outlet. The aerosol is then directed at the surface of the component body, where the aerosol jet impacts the surface with high velocity. The particles break up into solid nanosized fragments, forming a coating.

In another embodiment, a dielectric inductive power window 312 is provided by first providing a YOF component body. PVD, AD, or APS is used to deposit a YOF coating on the component body.

In another embodiment, the component is a gas injector 340. In some semiconductor processing chamber systems 300, gas injectors 340 may provide different gases or gas ratios to different zones. In an example, a central gas injector may provide gas to a central part of a semiconductor processing chamber 304 and edge gas injectors may provide gas to a peripheral part of a semiconductor processing chamber 304. Both central and edge gas injectors may be provided by this embodiment. In this embodiment, a component body of alumina is formed using additive manufacturing or droplet-based net-form manufacturing. Additive manufacturing is a manufacturing process that builds 3D objects by adding a layer-upon-layer of material. 3D printing is an example of additive manufacturing. An alumina coating may be formed by APS

In another embodiment, a gas injector may have a component body of YAG. In an embodiment, the component body is a single crystal of YAG. A YAG coating is deposited by PVD. In another embodiment, a gas injector component comprises a component body and coating both made of yttria, YOF, or yttrium(III) fluoride (YF₃).

In other embodiments, the component is an edge ring 360 that is used to surround a process wafer 366 being processed. In one embodiment, a ring shaped component body of the etch ring 360 is made of alumina. One of APS, CVD, and ALD is used to deposit an alumina coating on the component body. In another embodiment, the component body and coating are titania (titanium oxide). In another embodiment, the component body and coating are one of yttria, YOF, and yttrium(III) fluoride (YF₃).

In another embodiment, FIG. 4 is a schematic cross-sectional view of part of a component 400 with a component body 404 of another embodiment. In this embodiment, the coating comprises a first coating 420a applied to the component body 404, and a second coating 420b applied to the first coating 420a. The first coating 420a, the second coating 420b, and the component body 404 all have the same chemical composition. In this embodiment, the second coating 420b is applied using a different deposition process than the process used to apply the first coating 420a so that the density of the first coating 420a is different than the density of the second coating 420b.

In some embodiments, the first coating 420a is denser than the second coating 420b. In such embodiments, the first coating 420a may be applied by CVD, PVD, or AD, and the second coating 420b is applied by APS. In other embodiments, the second coating 420b is denser than the first coating 420a. In such embodiments, the first coating 420a may be applied by APS, and the second coating 420b may be applied by AD or CVD. In an alternative, the first coating 420a is applied by ALD, and the second coating 420b is applied by APS. In some embodiments, the denser second coating 420b may be used as a sealed, glued, or barrier coating.

In another embodiment, a method for conditioning a component body of a used component of a semiconductor processing chamber is provided. The entire component and component body are made of a dielectric material, such as alumina. After use in a semiconductor processing chamber for processing a plurality of wafers, a semiconductor processing facing surface may become degraded. The component is removed from the semiconductor processing chamber. In an embodiment, at least part of the semiconductor processing facing surface is stripped. In an embodiment, the stripping comprises a wet clean or acid stripping. Other cleaning and processing steps may be performed on the semiconductor processing facing surface and the component. A coating of the dielectric material is deposited on at least the semiconductor processing surface of the component body. The coating has a different morphology and crystal structure than the component body and semiconductor processing facing surface. The depositing the coating may be performed by one or more of chemical vapor deposition, atomic layer deposition, physical vapor deposition, suspension plasma spraying, aerosol deposition, and thermal spraying. In some embodiments, the coating has a thickness between 30 nm and 150 microns. In some embodiments, the coating is at least one of a metal oxide, metal oxyfluoride, and metal fluoride, such as one or more of alumina, yttria, yttrium stabilized zirconia, yttrium oxyfluoride, yttrium (III) fluoride, and yttrium aluminum oxide. The reconditioned component is placed in a semiconductor processing chamber and then used to process wafers. In this embodiment, the coating has a thickness in the range of 30 nm to 600 microns. In various embodiments, the coating may have a thickness in one or more of the ranges of 30 nm to 200 nm, 1 micron to 20 microns, 10 microns to 250 microns, or 300 microns to 600 microns depending on the coating process and the application.

Previously, used components would be discarded. Providing a new component is expensive. The ability to provide a reconditioned component at a low cost and with erosion resistance and similar properties as a new component, reduces cost of ownership and reduces the environmental impact. In other embodiments, a second coating may be deposited over the coating, where the second coating is of the same material as the coating, but has a different density, morphology, or crystal structure than the coating. For example, in an embodiment, the second coating may be more dense than the coating. The density may be determined by the deposition process and deposition parameters.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for making a component for use in a semiconductor processing chamber, comprising:
forming a component body from a dielectric material, wherein the component body has a semiconductor processing facing surface; and
depositing a coating of the dielectric material over at least the semiconductor processing facing surface of the component body.

2. The method, as recited in claim 1, further comprising machining the component body before depositing the coating of the dielectric material.

3. The method, as recited in claim 1, wherein the semiconductor processing facing surface of the component body has a different surface morphology than the coating and wherein the component body and the semiconductor processing facing surface are made of a single dielectric material.

4. The method, as recited in claim 1, wherein the forming the component body comprises a sintered ceramic dielectric material.

5. The method, as recited in claim 1, wherein the forming the component body comprises using an additive manufacturing process or droplet-based net-form manufacturing process.

6. The method, as recited in claim 1, wherein the component body and the coating have different crystal structures.

7. The method, as recited in claim 1, wherein the depositing the coating is by at least one of chemical vapor deposition, atomic layer deposition, physical vapor deposition, suspension plasma spraying, aerosol deposition, and thermal spraying.

8. The method, as recited in claim 1, wherein the coating has a thickness between 30 nm and 600 microns.

9. The method, as recited in claim 1, wherein the depositing the coating over the semiconductor processing facing surface of the component body comprises depositing a first coating of the dielectric material at a first density and depositing a second coating of the dielectric material over the first coating at a second density, wherein the first density is different than the second density.

10. The method, as recited in claim 1, wherein the dielectric material is at least one of a metal oxide, metal oxyfluoride, and metal fluoride.

11. The method, as recited in claim 1, wherein the dielectric material comprises at least one of alumina, yttria, yttrium stabilized zirconia, yttrium oxyfluoride, yttrium (III) fluoride, and yttrium aluminum oxide.

12. A component for use in a semiconductor processing chamber, comprising:
a component body of a dielectric material, wherein the component body has a semiconductor processing facing surface; and
a coating of a dielectric material on at least the semiconductor processing facing surface, wherein the dielectric material of the component body has a same stoichiometry as the dielectric material of the coating.

13. The component, as recited in claim 12, wherein the component body has a different density than the coating.

14. The component, as recited in claim 12, wherein the component body and the coating are made of one of alumina, yttria, yttrium stabilized zirconia, yttrium oxyfluoride, yttrium (III) fluoride, and yttrium aluminum oxide.

15. The component, as recited in claim 12, wherein the coating has a thickness in a range between 30 nm and 600 microns.

16. The component, as recited in claim 12, wherein the component body has at least one borehole passing through the component body and wherein the component body has a different density than the coating.

17. The component, as recited in claim 12, wherein the component is at least one of an edge ring and a power window.

18. The component, as recited in claim 12, wherein the component body dielectric material is a sintered ceramic dielectric material and the coating dielectric material is a non-sintered ceramic dielectric material.

19. The component, as recited in claim 12, wherein the component body forms at least one of a showerhead, gas injector, chamber wall, edge ring, and power window.

20. A method of reconditioning a component body of a dielectric material for use in a semiconductor processing chamber, comprising:
stripping at least part of a semiconductor processing facing surface of the component body; and
depositing a coating of the dielectric material on the component body.

21. The method, as recited in claim 20, wherein the semiconductor processing facing surface of the component body has a different surface morphology than the coating.

22. The method, as recited in claim 20, wherein the component body and the coating have different crystal structures.

23. The method, as recited in claim 20, wherein the depositing the coating is by at least one of chemical vapor deposition, atomic layer deposition, physical vapor deposition, suspension plasma spraying, aerosol deposition, and thermal spraying.

24. The method, as recited in claim 20, wherein the coating has a thickness between 30 nm and 600 microns.

25. The method, as recited in claim 20, wherein the depositing the coating over the semiconductor processing facing surface of the component body comprises depositing a first coating of the dielectric material at a first density and depositing a second coating of the dielectric material over the first coating at a second density, wherein the first density is different than the second density.

26. The method, as recited in claim 20, wherein the dielectric material is at least one of a metal oxide, metal oxyfluoride, and metal fluoride.

27. The method, as recited in claim 20, wherein the dielectric material comprises at least one of alumina, yttria, yttrium stabilized zirconia, yttrium oxyfluoride, yttrium (III) fluoride, and yttrium aluminum oxide.
